(19) United States
(12) Patent Application Publication
(10) Pub. No.: US 2022/0197141 A1
(43) Pub. Date: Jun. 23, 2022

(54) PHOTORESIST UNDERLAYER COMPOSITIONS AND PATTERNING METHODS

(71) Applicant: ROHM AND HAAS ELECTRONIC MATERIALS LLC, Marlborough, MA (US)

(72) Inventors: Joshua Kaitz, Watertown, MA (US); Michael Finch, Chelmsford, MA (US); Paul J. LaBeaume, Auburn, MA (US); Shintaro Yamada, Shrewsbury, MA (US); Suzanne M. Coley, Mansfield, MA (US)

(21) Appl. No.: 17/124,743

(22) Filed: Dec. 17, 2020

(51) Int. Cl. G03F 7/11; C08F 12/08; C08F 12/22; C09D 125/14; C09D 125/18; C23C 16/02; C23C 16/20; C23C 16/455; G03F 7/16; H01L 21/027

(52) U.S. Cl. CPC G03F 7/11; C08F 12/08; C08F 12/22; C09D 125/14; C09D 125/18; H01L 27/11551; C23C 16/20; C23C 16/45523; G03F 7/167; H01L 21/0276; C23C 16/0272

(57) ABSTRACT

A method of forming a pattern on a substrate, the method including:
forming a photoresist underlayer over a surface of the substrate, the photoresist underlayer formed from a composition including a polymer having a glass transition temperature of less than 110° C. and a solvent;
subjecting the photoresist underlayer to a metal precursor, where the metal precursor infiltrates a free volume of the photoresist underlayer; and
exposing the metal precursor-treated photoresist underlayer to an oxidizing agent to provide a metallized photoresist underlayer.

### FIELD

The present invention relates generally to field of manufacturing electronic devices, and more specifically to the field of materials for use in semiconductor manufacture.

### BACKGROUND

Multilayer resist processes (such as three- and four-layer processes) have been devised where a high aspect ratio is desired. Such multilayer processes use a resist top layer, one or more middle layers, and a bottom layer (or underlayer). In such multilayer resist processes, the top photoresist layer is imaged and developed in typical fashion to provide a resist pattern. The pattern is then transferred to the one or more middle layers, typically by etching. Each middle layer is selected with sufficient etch selectivity such that a different etch process may be used such as different plasma etches for pattern transfer. Finally, the pattern is transferred to the underlayer by etching such as reactive ion etch (ME). Such middle layers may be composed of various materials. The underlayer material is selected to provide desired antireflective properties, planarizing properties, as well as etch selectivity.

Photoresist underlayer compositions and, in particular, Spin-on Carbon (SOC) compositions, are used in the semiconductor industry as etch masks for lithography in advanced technology nodes for integrated circuit manufacturing. These compositions are often used in tri-layer and quad-layer photoresist integration schemes, where an organic or silicon containing anti-reflective coating and patternable photoresist layers are also used in the full film stack.

An ideal photoresist underlayer material should possess certain specific characteristics: it should be capable of being cast onto a substrate by a spin-coating process, should be thermally set upon heating with low out-gassing and sublimation, should be soluble in common solvents for good spin bowl compatibility, should have appropriate optical properties to work in conjunction with the anti-reflective coating layer to impart low reflectivity necessary for photoresist imaging, and should have high thermal stability to avoid being damaged during later processing steps. In addition to these requirements, the ideal photoresist underlayer material has to provide a planar film upon spin-coating and thermal curing over a substrate with topography and sufficient dry etch selectivity to material layers located above and below the photoresist underlayer in order to transfer the patterns into the substrate in an accurate manner.

As leading nodes in semiconductor fabrication require patterning of extremely high aspect ratio features, especially in the case of 3D NAND memory architectures, semiconductor manufacturers are often pushed to the technical limit of spin-on hardmask layers to serve as etch masks. In order to produce high aspect ratio contacts for 3D NAND applications, manufacturers require spin-on materials with further improved etch resistance compared to known materials. In order to meet this need, a process of vapor phase infiltration was developed whereby metal precursors are infused into an organic film and then oxidized to metal oxides to generate an organic-inorganic hybrid film. In the case of thick SOC films, however, the metal infiltration process can be somewhat limited, e.g., if metal precursors interact with film components during diffusion and are prevented from diffusing to the bottom of the film. Accordingly, metal diffusion relative to film depth will essentially become blocked at some point in the film, or lead to metal infiltrated films with a relatively steep concentration gradients of the infiltrated metal precursor.

There remains a need for new photoresist underlayers with substantially improved etch selectivity, particularly improved etch resistance to O₂ and CF₄ plasmas, and the use of such materials, for example, in 3D NAND memory architectures or integrated circuits with high aspect ratio features.

### SUMMARY

A method of forming a pattern on a substrate, the method comprising:

forming a photoresist underlayer over a surface of the substrate, wherein the photoresist underlayer is formed from a composition comprising a polymer having a glass transition temperature of less than 110° C. and a solvent;

subjecting the photoresist underlayer to a metal precursor, wherein the metal precursor infiltrates a free volume of the photoresist underlayer; and

exposing the metal precursor-treated photoresist underlayer to an oxidizing agent to provide a metallized photoresist underlayer.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not.

It will be understood that although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It will be understood that the term “polymer” refers to a homopolymer as well as a copolymer prepared from two or more monomers. The polymer is prepared with procedures known in the art.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O”; “carboxylic acid group” refers to a group having the formula “—C(═O)—OH”; “cycloalkyl group” refers to a monovalent group having one or more saturated rings in which all ring members are carbon. Examples of a cycloalkyl group may include a cyclopentyl group, a 1-methylcyclopentyl, a 2-ethylcyclopentyl, a cyclohexyl group, a 1-ethylcyclohexyl group, a 2-methylcyclohexyl group, a 1-adamantyl group, a 2-adamantyl group, or a 2-methyl-2-adamantyl group.

The term “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O—”; “alkenylene group” refers to an alkenyl group having a valence of at least two; “cycloalkenyl group” refers to a cycloalkyl group having at least one carbon-carbon double bond; “alkynyl group” refers to a monovalent hydrocarbon group having at least one carbon-carbon triple bond.

The term “aromatic group” denotes the conventional idea of aromaticity as defined in the literature, in particular in IUPAC 19, and refers to a monocyclic or polycyclic aromatic ring system that includes carbon atoms in the ring or rings, and optionally may include one or more heteroatoms independently selected from N, O, and S instead of a carbon atom or carbon atoms in the ring or rings; “aryl group” refers to a monovalent, monocyclic or polycyclic aromatic group containing only carbon atoms in the aromatic ring or rings, and may include a group with an aromatic ring fused to at least one cycloalkyl or heterocycloalkyl ring. The monocyclic or polycyclic aromatic ring group can include two or more monocyclic or polycyclic aromatic rings linked by a single bond.

The term “arylene group” refers to an aryl group having a valence of at least two; “alkylaryl group” refers to an aryl group that has been substituted with an alkyl group; “arylalkyl group” refers to an alkyl group that has been substituted with an aryl group; “aryloxy group” refers to “aryl-O—”; and “arylthio group” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently selected from N, O, S, Si, or P; “heteroatom-containing group” refers to a substituent group that includes at least one heteroatom; “heteroalkyl group” refers to an alkyl group having 1-4 heteroatoms instead of carbon atoms; “heterocycloalkyl group” refers to a cycloalkyl group with one or more N, O or S atoms instead of carbon atoms; “heterocycloalkylene group” refers to a heterocycloalkyl group having a valence of at least two; “heteroaryl group” refers to an aryl group having 1 to 3 separate or fused rings with one or more N, O or S atoms as ring members instead of carbon atoms; and “heteroarylene group” refers to a heteroaryl group having a valence of at least two.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present.

The symbol “*” represents a bonding site (i.e., point of attachment) of a repeating unit.

“Substituted” means that at least one hydrogen atom on the group is replaced with another group, provided that the designated atom's normal valence is not exceeded. When the substituent is oxo (i.e., ═O), then two hydrogens on the carbon atom are replaced. Combinations of substituents or variables are permissible. Exemplary groups that may be present on a “substituted” position include, but are not limited to, nitro (—NO₂), cyano (—CN), hydroxyl (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, C₂₋₆ alkyl ester (—C(═O)O-alkyl or —OC(═O)-alkyl), C₇₋₁₃ aryl ester (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio thiocyano (—SCN), sulfonate (—SO₃), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

A Spin-on Carbon (SOC) composition or polymer should satisfy one or more of the following properties or characteristics; capable of being cast onto a substrate by a spin-coating process, thermal-set upon heating with low out-gassing and sublimation, soluble in common solvents for good spin bowl compatibility, possess appropriate optical properties to work in conjunction with the anti-reflective coating layer to impart low reflectivity necessary for photoresist imaging, or have high thermal stability so as to not be damaged during later processing steps. Furthermore, the resulting cured photoresist underlayer should have sufficient dry etch selectivity to material layers located above and below the photoresist underlayer in order to accurately transfer the pattern into the substrate.

We describe a SOC composition that includes a polymer with a glass transition temperature (Tg) of less than 110° C. and a solvent, and the formation of a metallized photoresist underlayer on a substrate. We also describe a metal infiltration process whereby a metal precursor is infused into the photoresist underlayer. The infused metal precursor is then oxidized to form a metallized site within the photoresist underlayer, e.g., a metal oxo site, to generate a metallized photoresist underlayer. Accordingly, in addition to one or more of the above SOC properties/characteristics above, the photoresist underlayer should exhibit sufficient metal precursor diffusion into the underlayer in order to achieve a greater degree of etch resistance or selectivity, and in some instances, a relatively shallow concentration gradient of the metal precursor from a surface of the metallized photoresist underlayer.

During our development of advanced photoresist underlayer materials we observed that photoresist underlayers that include one or more polymers with a glass transition temperature (Tg) of less than 110° C. can be effectively metallized to provide a metallized photoresist underlayer. Moreover, the metallized underlayer can have outstanding etch resistance to oxygen plasma RIE, fluorinated plasma RIE, and sputtering by ion-beam etching. The enhancement of etch resistance of the metallized photoresist underlayer to fluorinated plasma RIE is of particular interest. In contrast, a photoresist underlayer comprising a polymer having a similar polymer backbone or similar side chains, e.g., in the case of a polymer with different mole ratios of the same polymerized monomer units, but with a Tg greater than 110° C., and which has been metallized under identical metal precursor/oxidation conditions, does not have as satisfactory metal precursor penetration depth into the underlayer, and therefore, not likely meet the metal infiltration requirements and consequently, the etch resistance or selectivity requirements, of an applied SOC composition in the described metallization process.

We describe a method of forming a pattern on a substrate. The method includes:
forming a photoresist underlayer over a surface of the substrate, wherein the photoresist underlayer is formed from a composition comprising a polymer having a glass transition temperature of less than 110° C. and a solvent;
subjecting the photoresist underlayer to a metal precursor, wherein the metal precursor infiltrates a free volume of the photoresist underlayer; and
exposing the metal precursor-treated photoresist underlayer to an oxidizing agent to provide a metallized photoresist underlayer.

In an embodiment of the above method, prior to the subjecting of the photoresist underlayer to the metal precursor, the method further includes:
forming an antireflective coating layer over the photoresist underlayer and a photoresist layer over the antireflective coating layer;
exposing the photoresist layer to activating radiation and developing the exposed photoresist layer to form a photoresist pattern; and
transferring the photoresist pattern by etching to the antireflective coating layer and the photoresist underlayer.

In an embodiment, the polymer has a glass transition temperature of less than 100° C., less than 90° C., less than 80° C., less than 70° C., or less than 60° C. For example, the polymer has a glass transition temperature of greater than 0° C. and less than 100° C., greater than 10° C. and less than 90° C., greater than 20° C. and less than 90° C., or greater than 20° C. and less than 80° C. The glass transition temperature of the polymer is determined by differential scanning calorimetry (DSC) using methods known in the polymer art. Moreover, the Tg of polymer is to be determined prior to the preparation of the SOC composition. Accordingly, if the SOC composition is a mixture of two or more polymers infra then the DSC measurement is to be made for each polymer in the mixture of polymers, and not from a DSC measurement of the mixture.

The polymer may include polymerized units of monomer units chosen from acrylates, methacrylates, acrylamides, methacrylamides, vinyl ethers, vinyl aromatics, or a combination thereof. As noted, the polymer can be homopolymer, a copolymer, or a mixture of polymers including a homopolymer and a copolymer. For example, the SOC composition can include a mixture of two or more homopolymers, two or more copolymers, or one or more homopolymers and one or more copolymers. If the polymer of the SOC composition is a mixture of two or more polymers than at least one polymer must have a Tg of less than 110° C.

In an embodiment, if the polymer is a mixture of two or more polymers, the polymer with a Tg of less than 110° C. accounts for at least 40 wt % of the total weight of polymer in the SOC composition. For example, the polymer with a Tg of less than 110° C. can account for at least 50 wt %, at least 65 wt %, or at least 75 wt % of the total weight of polymer in the SOC composition.

The polymer may include a functional group on a side chain chosen from a keto-carbonyl, an ester, a hydroxy, acetal, ketal, carboxylic acid, amide, carbamate, urea, carbonate, aldehyde, imide, sulfonic acid, sulfonate ester, or a combination thereof.

The functional group on a polymer side chain is likely to play a role in the degree of metallization of the polymer, i.e., the photoresist underlayer, resulting from a bonding or non-bonding interaction with the metal precursor as the precursor diffuses through the photoresist underlayer. In other words, the functional group on a polymer side chain may facilitate the anchoring or positioning of the metal precursor in the photoresist underlayer, and therefore, the functional group may have some role in the concentration (or concentration gradient) of metallization (metal sites) throughout the photoresist underlayer following the oxidation of the metal precursor.

The exposing of the metal precursor-treated photoresist underlayer to an oxidizing agent results in the presence of metal oxide sites in the photoresist underlayer. For example, the exposure of the metal precursor-treated photoresist may result in the formation of metal-oxo or metal amide sites in the metallized photoresist underlayer. In an embodiment, the metal-oxo/amide sites may include a direct bond or a coordinate bond to an oxygen or nitrogen atom of the polymer functional group. The exact chemical or structural bonding of the metallization of the photoresist underlayer is not important to the overall described process of metallization and glass transition temperature of the polymer. In some instances, the degree or the structural characterization of the metal sites resulting from metallization may be followed spectroscopically, e.g., by using IR spectroscopy, using methods known in the art.

In an embodiment, the polymer comprises polymerized units including a monomer unit of Formula (1)

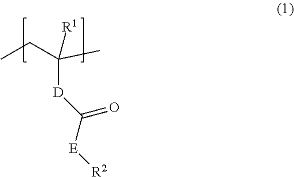

wherein in Formula (1),

D is absent, —O—, —(CHR^{a})ₙ—, —(CHR^{a}CHR^{b}O)ₘ—, optionally substituted C₆₋₁₄ arylene, optionally substituted C₃₋₁₈ heteroarylene, optionally substituted C₅₋₁₂ cycloalkylene, or a combination thereof, wherein each R^{a} and each R^{b} is independently hydrogen, or substituted or unsubstituted C₁₋₆ alkyl, and n is an integer of 1 to 12, and m is an integer of 1 to 8;

E is absent, —O—, —NR^{N}—, or E can join with D to from a ring;

R¹ and R^{N} are independently hydrogen, or substituted or unsubstituted C₁₋₆ alkyl; and

R² is hydrogen, substituted or unsubstituted C₁₋₁₆ alkyl, substituted or unsubstituted C₁₋₁₆ heteroalkyl, substituted or unsubstituted C₅₋₂₀ cycloalkyl, substituted or unsubstituted C₃₋₂₀ heterocycloalkyl, substituted or unsubstituted C₂₋₁₆ alkenyl, substituted or unsubstituted C₂₋₁₆ alkynyl, substituted or unsubstituted C₆₋₁₈ aryl, substituted or unsubstituted C₇₋₃₀ arylalkyl, substituted or unsubstituted C₇₋₃₀ alkylaryl, substituted or unsubstituted C₃₋₁₈ heteroaryl, substituted or unsubstituted C₄₋₃₀ heteroarylalkyl, or R² can join with D to form a ring.

In an embodiment, D is absent, —O—, —(CHR^{a})ₙ—, optionally substituted C₆₋₁₄ arylene or combination thereof, where n is an integer of 1 to 8; E is absent or —O—; and R² is hydrogen, substituted or unsubstituted C₁₋₁₀ alkyl, substituted or unsubstituted C₁₋₁₀ heteroalkyl with a total of one to four ether, ester, amide, or —C(O)— groups, unsubstituted C₆₋₁₄ aryl, C₆₋₁₄ aryl substituted with —OR³, —C(O)OR³, —C(O)N(R^{N})R³, or —C(O)R³, unsubstituted C₃₋₁₂ heteroaryl, or C₃₋₁₂ heteroaryl substituted with —OR³, —C(O)OR³, —C(O)N(R^{N})R³, or —C(O)R³, wherein R³ is H, or substituted or unsubstituted C₁₋₆ alkyl.

In an embodiment, R² is an unsubstituted C₆₋₁₄ aryl, a C₆₋₁₄ aryl substituted with —R³, —OR³, —OC(O)R³—, —C(O)OR³, —C(O)N(R^{N})R³, or —C(O)R³, an unsubstituted C₃₋₁₂ heteroaryl, a C₃₋₁₂ heteroaryl substituted with —OR³, —C(O)OR³, —C(O)N(R^{N})R³, or —C(O)R³, where R³ is defined above.

Examples of the C₁₋₁₀ alkyl group include a methyl group, an ethyl group, an n-propyl group, an i-propyl group, an n-butyl group, a 2-methylpropyl group, a 1-methylpropyl group, a t-butyl group, and the like. Examples of the C₁₋₉ alkoxy group include a methoxy group, an ethoxy group, an n-propoxy group, an i-propoxy group, an n-butoxy group, a 1-methylpropoxy group, a 2-methylpropoxy group, a t-butoxy group, and the like. Examples of —C(O)OR³ include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, and the like.

In an embodiment, the polymer is a copolymer that includes polymerized units of two or more different monomer units of Formula 1, e.g., three or more different monomer units of Formula 1. For example, if D is absent and E is —O— or —NR^{N}—, then R² is chosen from a substituted or unsubstituted C₁₋₁₆ alkyl, substituted or unsubstituted C₅₋₂₀ cycloalkyl, substituted or unsubstituted C₆₋₁₈ aryl, substituted or unsubstituted C₇₋₃₀ alkylaryl, or a substituted or unsubstituted C₃₋₁₈ heteroaryl. In one such instance, the substituted or unsubstituted C₁₋₁₆ alkyl is chosen from a substituted or unsubstituted C₁-8 alkyl such as a linear C₁₋₆ alkyl, optionally substituted with OH, OR²¹, or a methyl ester, where R²¹ is a C₁₋₄ alkyl. In another such instance, the substituted or unsubstituted C₆₋₁₈ aryl is chosen from a substituted or unsubstituted phenyl, naphthyl, or anthracenyl. Substitution of a phenyl or naphthyl with a C₁₋₄ alkyl, C₁₋₄ alkoxy, or a methyl ester, is of interest.

In an embodiment, the polymer is a copolymer that includes polymerized units of two or more different monomer units of Formula 1 including at least one monomer unit where R² is a C₂₋₈ alkyl optionally substituted with —OH, OR²¹, or a methyl ester, where R²¹ is a C₁₋₄ alkyl. The presence of —OH on a sidechain of the polymer can be used to from crosslinks in the SOC photoresist underlayer. Also, we have observed that the addition of such polymerized units in the polymer tends to lower the Tg of the polymer. A C₃₋₈ alkyl can be linear or branched. For example, the C₃₋₈ alkyl can be a linear C₃₋₈ alkyl that is optionally substituted. Substituents of interest include —OH, OR²¹, —C(O)Me, —C(O)OH, or —O-phenyl.

In a particular embodiment where D is absent and E is —O— or —NR^{N}—, and R² is a substituted or unsubstituted C₃₋₁₀ alkyl, the aliphatic character of R² provides a polymer with a relatively lower Tg, and therefore, such monomer units of Formula (1) may be present from 10 mol % to 60 mol %.

Some exemplary monomer units of Formula (1) are indicated below.

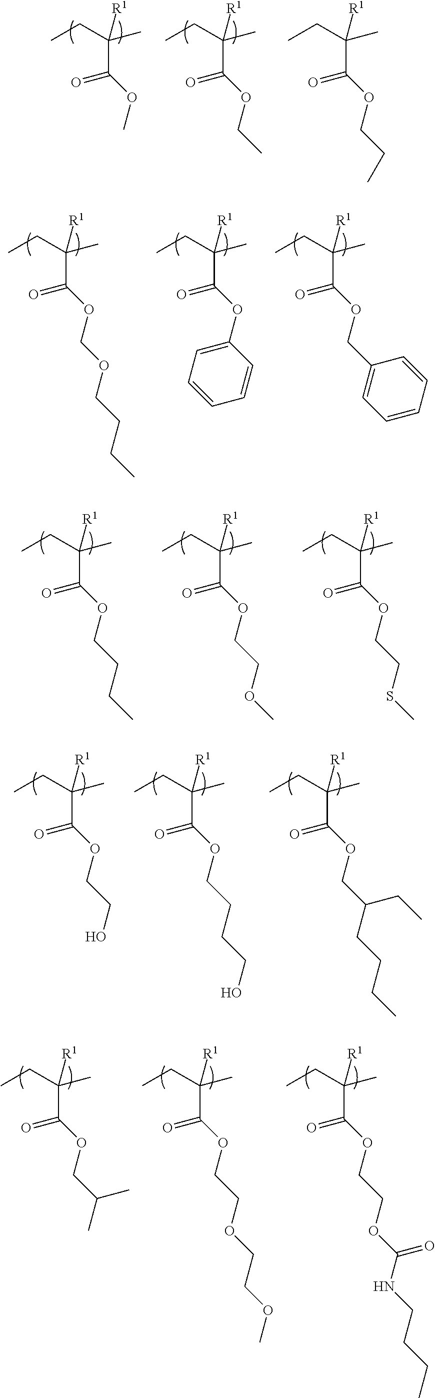

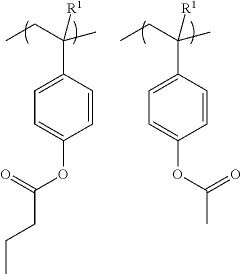

In an embodiment, the polymer comprises polymerized units including a monomer unit of Formula (2)

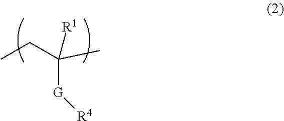

wherein in Formula (2),

G is absent, —(CHR^{a})ₙ—, —(CHR^{a}cHR^{b}O)ₘ—, —O—, —C(O)O—, —C(O)OR⁵—, —C(O)—, —C(O)N(R^{N})—, optionally substituted C₆₋₁₄ arylene, optionally substituted C₃₋₁₃ heteroarylene, or optionally substituted C₅-C₁₂ cycloalkylene, wherein R¹, R^{N}, each R^{a} and each R^{b}, is independently hydrogen, optionally substituted C₁₋₆ alkyl, an optionally substituted C₆₋₁₄ aryl, or an optionally substituted C₃₋₁₃ heteroaryl; and n is an integer of 1 to 12, and m is an integer of 1 to 8;

R⁴ is hydrogen, optionally substituted C₁₋₁₀ alkyl, optionally substituted C₁₋₁₀ heteroalkyl with a total of one to four ether, ester, amide, or —C(O)— groups, optionally substituted C₂₋₁₀ alkenyl, optionally substituted C₂₋₁₀ alkynyl, optionally substituted C₆₋₁₄ aryl, or optionally substituted C₃₋₁₂ heteroaryl, and

R⁵ is an optionally substituted C₁₋₄ alkylene or C₂₋₄ alkenylene.

In an embodiment, G is absent, —(CHR^{a})ₙ—, —O—, —C(O)O—, or —C(O)OR⁵—, and R⁴ is phenyl, naphthyl, or anthracenyl, each of which is optionally substituted with —OR³, —C(O)OR³, —C(O)N(R^{N})R³, or —C(O)R³, wherein R³ is hydrogen, CN, optionally substituted C₁₋₆ alkyl, C₂₋₄ alkenyl, C₂₋₄ alkynyl, an optionally substituted C₆₋₁₄ aryl, or an optionally substituted C₃₋₁₃ heteroaryl, and R⁴, R⁵, R^{N}, and R^{a} are defined above.

In an embodiment, R⁴ is an unsubstituted C₆₋₁₄ aryl, a C₆₋₁₄ aryl substituted with —R³, —OR³, —OC(O)R³—, —C(O)OR³, —C(O)N(R^{N})R³, or —C(O)R³, an unsubstituted C₃₋₁₂ heteroaryl, a C₃₋₁₂ heteroaryl substituted with —OR³, —C(O)OR³, —C(O)N(R^{N})R³, or —C(O)R³, and R³ is defined above.

In an embodiment, a polymer can include monomer units of Formula (1) and Formula (2), for example, the polymer may include from 1 mol % to 99 mol % of Formula (1) and 99 mol % to 1 mol % of Formula (2), 20 mol % to 80 mol % of Formula (1) and 80 mol % to 20 mol % of Formula (2), or 30 mol % to 70 mol % of Formula (1) and 70 mol % to 30 mol % of Formula (2). It is to be understood, that the polymer can include monomer units other than the monomer units of Formulae (1) and (2).

In a particular embodiment where G of Formula (2) is absent, —(CHR^{a})ₙ—, —O—, —C(O)O—, or —C(O)OR⁵—, and R⁴ is phenyl, naphthyl, or anthracenyl, each of which is optionally substituted with —OR³, —C(O)OR³, —C(O)N(R^{N})R³, or —C(O)R³, wherein R³, R⁵, and R^{N} is defined above. The aromatic character of R⁴ provides a polymer with greater carbon content, and therefore, the monomer units of Formula (2) may be present from 40 mol % to 80 mol %.

The SOC composition may include one or more of the following polymers. In the polymer P3 below, q is about 10-15.

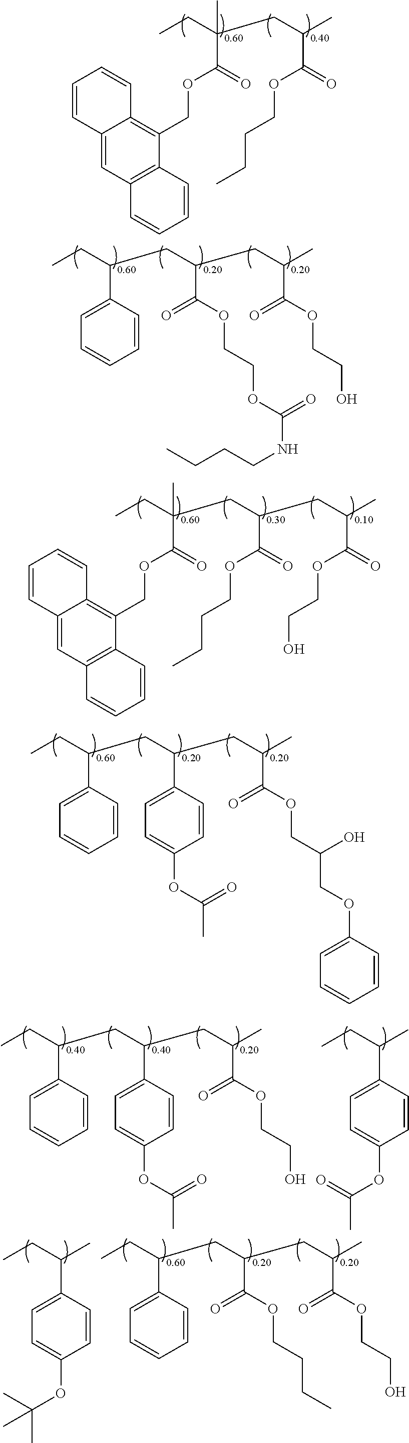

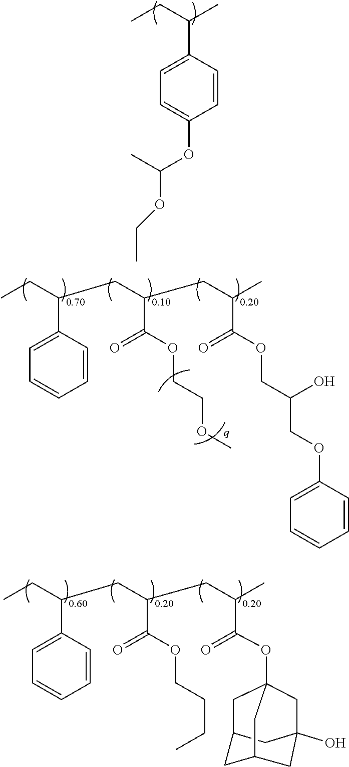

We identify four physicochemical features of the metal precursor or the polymer matrix that may have a role in the sorption, diffusion, and entrapment kinetics of the metal precursor in a photoresist underlayer: (1) size and shape of the metal precursor, (2) free volume of the polymer, (3) tortuosity of the free volume, and (4) reactivity or coordination between the precursor and polymer functional groups. See, Losego, M. D. et al., Material Horizons 2017, 4, 747-71.

The process of metallization of applied polymer materials is known, and the process, at times, is referred to in the art, for example, as “Multiple Pulsed Infiltration” (MPI), “Sequential Infiltration Synthesis” and “Sequential Vapor Infiltration”, however, each of these processes are merely differentiated by metal precursor dosing sequence. Each process entails diffusing metal precursor molecule into an applied polymer and then entrapping the precursor in the polymer film.

In an embodiment, if the metal precursor is present in a carrier gas or as a vapor, gas delivery pulse times, hold times, and cycle repetitions may vary, each of these processes ultimately yield similar, or substantially the same metallized polymer film. Accordingly, we use the term “Vapor Phase Infiltration (VPI)” to include each of the metal infiltration processes previously described in the art. The three steps in VPI processing described herein will typically include three modes of action: (1) sorption (or dissolution) of a gaseous metal (usually metalorganic) precursor into the applied SOC polymer; (2) transport (diffusion) of that metal precursor into the polymer matrix; and (3) entrapment (e.g., through a reaction or coordination) of the metal precursor within the bulk polymer, e.g., through a chemical or physical interaction with a functional group of the polymer. Vapor phase infiltration transforms the surface, subsurface, or bulk of the photoresist underlayer into new organic-inorganic hybrid material with markedly different properties than the non-metallized underlayer.

Likewise, in an embodiment, if the metal precursor is present in solution, delivery pulse times, hold times, and cycle repetitions may vary, and we use the term “Liquid Phase Infiltration (LPI)”. The three steps in LPI processing will typically include three modes of action: (1) sorption of a solution that includes the metal (usually metalorganic) precursor into the applied SOC polymer; (2) transport (diffusion) of that solution metal precursor into the polymer matrix; and (3) entrapment (e.g., through a reaction or coordination) of the metal precursor within the bulk polymer, e.g., through a chemical or physical interaction with a functional group of the polymer. Liquid phase infiltration transforms the surface, subsurface, or bulk of the applied SOC film into a new organic-inorganic hybrid material with markedly different properties.

The metalized photoresist underlayer is used as an etch mask for generating high aspect-ratio nanostructures via plasma etching. For example, the photoresist underlayer is infiltrated with a metal precursor, e.g., Al(Me)₃ (TMA), which is later oxidized in the presence of water (water vapor) to a metal oxide framework. In an embodiment, one can use an alternating exposure of the photoresist underlayer to the metal precursor then water in a deposition chamber. Appropriate exposure times are used for the metal precursor to allow the precursor to diffuse or permeate into the photoresist underlayer. Appropriate exposure time for the water is also used to ensure the oxidation reaction of the metal precursor with the water.

A variety of different gaseous or liquid metal precursors may be used in the metallization process. Exemplary metal precursors may include: trialkylates, trihalides or mixed alkylhalides of Group 13 (IIIA) metals such as boron, aluminum, or gallium, e.g. trimethylaluminum; tetraalkylates, tetrahalides or mixed alkylhalides of Group 4 (IVB) metals such as titanium, zirconium of hafnium, e.g, tetraalkyltitanium or tetrahalidetitanium, e.g., Ti(iso-propoxide)₄ or TiCl₄; trialkylates, trihalides or mixed alkylhalides of Group 5 (VB) metals such as vanadium, niobium, or tantalum; trihalides or hexahalides or mixed alkylhalides of Group 6 (VIB) metals such as chromium, molybdenum, or tungsten; metal alkyl, metal halide, or mixed metal alkyl/halides of cobalt, nickel, copper, tin, germanium, or zinc can also be used.

The depth of metallization into a patterned photoresist underlayer can in-part be controlled by temperature of the reaction chamber (i.e., photoresist underlayer) during the infiltration step of the metal precursor, the metal precursor, mode of subjecting the photoresist layer to a vapor or liquid, and the polymer of the photoresist underlayer. At times, it may be advantageous to infiltrate the sidewall edge region of the patterned photoresist underlayer, and thus, limit the amount of penetration into the bulk of the patterned underlayer. At other times, it may be advantageous to infiltrate the bulk of the photoresist underlayer. Of course, the degree or amount of exposure time will depend upon the desired aspect ratio of the patterned substrate. For example, for a given exposure time and photoresist underlayer, a relatively lower infiltration temperature may result in penetration at primarily the sidewalls, thereby leaving the bulk of the photoresist underlayer unexposed to the metal precursor (or non-metallized). Accordingly, for a given exposure time and photoresist underlayer, a relatively higher infiltration temperature would likely lead to greater penetration depth and greater uniformity of metallization across the bulk of the patterned photoresist underlayer.

In addition to etch-resistance enhancement, the metallization process described enhances and maintains the quality of the printed pattern from the photoresist underlayer to the substrate. Moreover, in many instances we observe little if any significant swelling of the photoresist underlayer following metallization.

A variety of different oxidants may be used in the metallization process to convert infiltrated metal precursors to metal oxides, metal fluorides, or other metal-containing species. Exemplary oxidants may include, but are not limited to water, oxygen, ozone, sulfur hexafluoride, hydrogen fluoride, hydrogen peroxide, and others.

Polymers of the invention may be prepared by procedures known in the art. One suitable procedure is to react one or more monomers of Formula (1), to react one or more monomers of Formula (2), or to react one or more monomers of Formulae (1) and (2) in a suitable solvent in the presence of a free radical initiator, such as V-601, with heating. Such polymers may be used as is, or may be further purified. Preferably, the polymers are further purified before use. Suitable polymer purification procedures are well-known to those skilled in the art. In general, the present polymers have a weight average molecular weight in the range of 900 to 100,000 g/mole, or 2,000 to 70,000 g/mole, and preferably from 3,000 to 65,000 g/mole as determined by gel permeation chromatography (GPC) using polystyrene standards. The present polymers may have any suitable polydispersity, such as from 1 to 10, and preferably from 1 to 5.

A suitable composition useful for forming a photoresist underlayer comprises one or more of the polymers described above, organic solvent, and optionally one or more additives chosen from cross-linkers, curing agents, and surfactants. It will be appreciated by those skilled in the art that other additives may suitably be used in the present compositions. Compositions of the invention may be prepared by combining the polymer, solvent, and any optional additives in any order. In many instances, the amount of the polymer in the SOC composition that is applied to a substrate is greater than 3 wt %, greater than 8 wt %, greater than 12 wt %, greater than 15 wt %, greater than 18 wt %, or greater than 20 wt %, and less than 60 wt %, less than 55 wt %, less than 50 wt %, or less than 40 wt %. For example, the amount of the polymer in the SOC composition that is applied to a substrate is in a range from 3 wt % to 50 wt %, from 8 wt % to 40 wt %, or from 15 wt % to 40 wt %. It will be appreciated by those skilled in the art that the concentration of the polymer in the SOC composition may be varied across a wide range and that the thickness of any film deposited by a spin-on technique depends on the concentration of the polymer in the solvent.

Any solvent or solvent mixture may be used in the SOC composition, provided that a sufficient amount of the polymeric reaction product is soluble in the solvent or solvent mixture. Such solvents include, but are not limited to, aromatic hydrocarbons, alcohols, lactones, esters, ethers, ketones, amides, carbonates, glycols, and glycol ethers. Mixtures of organic solvents may be used. Exemplary organic solvents include, without limitation, toluene, xylene, anisole, mesitylene, 2-methyl-1-butanol, 4-methyl-2-pentanol, methyl isobutyl carbinol, gamma-butyrolactone, ethyl lactate, methyl 2-hydroxyisobutyrate, propylene glycol methyl ether acetate (PGMEA), propylene glycol methyl ether (PGME), methyl 3-methoxypropionate (MMP), n-butyl acetate, N-methyl pyrrolidone, ethoxybenzene, benzyl propionate, benzyl benzoate, cyclohexanone, cyclopentanone, propylene carbonate, cumene, limonene, and mixtures thereof.

Optionally, the SOC compositions may further comprise one or more curing agents to aid in the curing of the photoresist underlayer. A curing agent is any component which causes curing of the polymer on the surface of a substrate. Preferred curing agents are acids and thermal acid generators. Suitable acids include, but are not limited to: arylsulfonic acids such as p-toluenesulfonic acid; alkyl sulfonic acids such as methanesulfonic acid, ethanesulfonic acid, and propanesulfonic acid; perfluoroalkylsulfonic acids such as trifluoromethanesulfonic acid; and perfluoroarylsulfonic acids. A thermal acid generator is any compound which liberates acid upon exposure to heat. Thermal acid generators are well-known in the art and are generally commercially available, such as from King Industries, Norwalk, Conn. Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators. The amount of such curing agents useful in the present compositions is well-known to those skilled in the art and is typically from 0 to 10 wt % relative to total solids, and preferably from 0 to 3 wt %.

The SOC composition may include one or more of the following additive compounds C1 and T1. The SOC composition may include one or more of Polyfox 656 (F1) or cyclohexanone (S1). See, Examples.

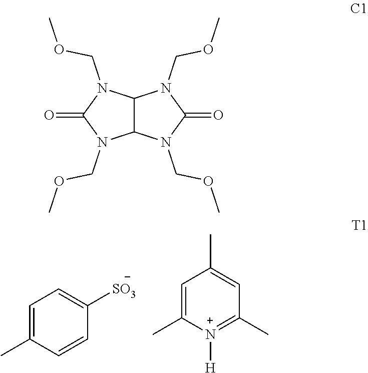

Compound C1 above is an example of a crosslinking agent that may be present in the SOC composition. A crosslinking agent will have has at least 2, and preferably at least 3, moieties capable of reacting with the polymer under suitable conditions, such as under acidic conditions. Other exemplary crosslinking agents include, but are not limited to, novolac resins, epoxy-containing compounds, melamine compounds, guanamine compounds, isocyanate-containing compounds, benzocyclobutenes, and the like, and preferably any of the foregoing having 2 or more, preferably 3 or more, and more preferably, substituents selected from methylol, C₁₋₁₀ alkoxymethyl, and C₂₋₁₀ acyloxymethyl. The amount of such cross-linking agents useful in the present compositions is well-known to those skilled in the art and is typically from 0 to 20 wt % relative to total solids, and preferably from 5 to 15 wt %.

The SOC compositions may optionally include one or more surface leveling agents (or surfactants). While any suitable surfactant may be used, such surfactants are typically non-ionic. Exemplary non-ionic surfactants are those containing an alkyleneoxy linkage, such as ethyleneoxy, propyleneoxy, or a combination of ethyleneoxy and propyleneoxy linkages. Further examples of surfactants include silicone surfactants or fluorochemical surfactants. Suitable non-ionic surfactants include, but are not limited to, octyl and nonyl phenol ethoxylates such as TRITON® X-114, X-100, X-45, X-15 and branched secondary alcohol ethoxylates such as TERGITOL™ TMN-6 (The Dow Chemical Company, Midland, Mich. USA) and PF-656 (Omnova Solutions, Beachwood, Ohio, USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. The amount of such surfactants useful in the present compositions is well-known to those skilled in the art, and typically is in the range of 0 to 5 wt % relative to total solids.

In another embodiment, we describe a method of forming a pattern on a substrate. The method includes in the following order:

forming a photoresist underlayer over a surface of the substrate, wherein the photoresist underlayer is formed from a composition comprising a polymer having a glass transition temperature of less than 110° C. and a solvent;

subjecting the photoresist underlayer to a metal precursor, wherein the metal precursor infiltrates a free volume of the photoresist underlayer;

exposing the metal precursor-treated photoresist underlayer to an oxidizing agent to provide a metallized photoresist underlayer;

forming an antireflective coating layer over the metallized photoresist underlayer and a photoresist layer over the antireflective coating layer;

exposing the photoresist layer to activating radiation and developing the exposed photoresist layer to form a photoresist pattern; and

transferring the photoresist pattern by etching to the antireflective coating layer and the photoresist underlayer.

In the above embodiment, the photoresist underlayer is subjected to the metal precursor, and then exposed to the oxidizing agent, to provide a metallized photoresist underlayer. The antireflective coating layer is then formed over the metallized photoresist underlayer, followed by the forming of the photoresist layer over the antireflective coating layer. The photoresist layer is then patterned using methods known in the art, and that pattern is transferred to the antireflective coating layer and the photoresist underlayer with one or more etching processes. Accordingly, the SOC composition is used in a multilayer resist process that includes forming an antireflective coating layer, e.g., a silicon-based oxide film, on a surface of the photoresist underlayer film, and subjecting the antireflective coating layer to wet or dry etching.

The SOC composition according to one embodiment is used in a multilayer resist process that includes forming a silicon-based oxide film on a surface of the photoresist underlayer, and subjecting the silicon-based oxide film to wet etching. Moreover, because the polymer used in the SOC composition has a Tg of less than 110° C. as noted above, the resulting photoresist underlayer may exhibit excellent adhesion to the substrate. It may be that any residual stress in the photoresist underlayer due to heating is reduced with a polymer with the stated glass transition temperature.

The SOC compositions are disposed on an electronic device substrate by spin-coating. In a typical spin-coating method, the present compositions are applied to a substrate which is spinning at a rate of 500 to 4000 rpm for a period of 15-90 seconds to obtain a desired layer of the SOC composition, and therefore, a polymer described herein on the substrate. It will be appreciated by those skilled in the art that the height of the polymeric layer (polymeric photoresist underlayer) may be adjusted by changing the spin speed as well as the polymer solid content of the SOC composition.

A wide variety of substrates may be used in the patterning methods, with electronic device substrates being typical. Suitable substrates include, for example, packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Such substrates may be any suitable size. Typical wafer substrate diameters are 200 mm to 300 mm, although wafers having smaller and larger diameters may be suitably employed according to the present invention. As used herein, the term “semiconductor substrate” includes any substrate having one or more semiconductor layers or structures which may optionally include active or operable portions of semiconductor devices. A semiconductor device refers to a semiconductor substrate upon which at least one microelectronic device has been or is being batch fabricated.

The substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Examples of the substrate include a wafer coated with an insulating film (e.g., silicon oxide, silicon nitride, silicon oxynitride, or polysiloxane) or a low-dielectric-constant insulating film (e.g., Black Diamond (manufactured by AMAT), SiLK (manufactured by Dow Chemical), or LKD5109 (manufactured by JSR Corporation)). A patterned substrate having a trench, a via, and the like may also be used.

The substrate may include one or more layers and patterned features. The layers may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. The layers can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating.

The applied photoresist underlayer composition is optionally soft-baked at a relatively low temperature to remove any solvent and other relatively volatile components from the composition. Exemplary baking temperatures may be from 60° C. o 170° C., although other suitable temperatures may be used. Such baking to remove residual solvent may be 10 seconds to 10 minutes, although longer or shorter times may suitably be used. When the substrate is a wafer, such baking step may be performed by heating the wafer on a hot plate.

A photoresist underlayer formed from the SOC composition typically has a dried layer thickness of from 10 nm to 50 μm, typically from 25 nm to 30 μm, and more typically from 50 to 5000 nm. The photoresist underlayer composition may be applied so as to substantially fill, preferably fill, and more preferably fully fill, a plurality of gaps on the substrate.

The applied photoresist underlayer composition is then cured to form a photoresist underlayer. The photoresist underlayer composition should be sufficiently cured such that the photoresist underlayer does not intermix, or minimally intermixes, with a subsequently applied layer, such as a photoresist or other organic or inorganic layer disposed directly on the photoresist underlayer. The photoresist underlayer composition may be cured in an oxygen-containing atmosphere, such as air, or in an inert atmosphere, such as nitrogen and under conditions, such as heating, sufficient to provide a cured coating layer. This curing step is preferably conducted on a hot plate-style apparatus, although oven curing may be used to obtain equivalent results. The curing temperature should be sufficient to effect curing throughout the layer, for example, sufficient to allow a curing agent such as a free acid to effect crosslinking, or to allow a thermal acid generator to liberate acid and the liberated acid to effect crosslinking where the curing agent is a thermal acid generator (TAG). Typically, the curing is conducted at a temperature of 150° C. or greater, and preferably 150° C. to 450° C. It is more preferred that the curing temperature is 180° C. or greater, still more preferably 200° C. or greater, and even more preferably from 200° C. to 400° C. The curing time is typically from 10 seconds to 10 minutes, preferably from 30 seconds to 5 minutes, more preferably from 45 seconds to 5 minutes, and still more preferably from 45 to 90 seconds. Optionally, a ramped or a multi-stage curing process may be used.

A ramped bake typically begins at a relatively low (e.g., ambient) temperature that is increased at a constant or varied ramp rate to a higher target temperature. A multi-stage curing process involves curing at two or more temperature plateaus, typically a first stage at a lower bake temperature and one or more additional stages at a higher temperature. For example, a ramped bake beginning at relatively low temperatures and then gradually increasing to the range of 200° C. to 325° C. can give acceptable results. It can be preferable in some cases to have a two-stage curing process, with the first stage being a lower bake temperature of less than 200° C., and the second stage being a higher bake temperature preferably between 200° C. and 400° C. Two stage curing processes facilitate uniform filling and planarization of pre-existing substrate surface topography, for example filling of trenches and vias. Conditions for such ramped or multi-stage curing processes are known to those skilled in the art, and may allow for omission of a preceding softbake process.

After curing of the photoresist underlayer composition, one or more intervening layers, such as a hardmask layer such as a metal hardmask layer, an organic or inorganic bottom antireflective coating (BARC) layer and the like, may be disposed over the cured photoresist underlayer. A photoresist layer may then be formed above the photoresist underlayer on one or more of the intervening layers. In this case, one or more intervening processing layers such as described above can be sequentially formed over the photoresist underlayer followed by formation of the photoresist layer. Determination of suitable layers, thicknesses and coating methods are well known to those skilled in the art.

A wide variety of photoresists may be suitably used in the methods of the invention and are typically positive-tone materials. Suitable photoresists include, for example, materials within the EPIC™ series of photoresists available from DuPont Electronics & Imaging (Marlborough, Mass.). Suitable photoresists may be either positive tone development or negative tone development resists.

An exemplary BARC layer includes a silicon-BARC, which may be spin coated on the underlayer followed by curing, or an inorganic silicon layer such as SiON or SiO₂ which may be deposited on the underlayer by chemical vapor deposition (CVD). Any suitable hardmask may be used and may be deposited on the underlayer by any suitable technique, and cured as appropriate. Optionally, an organic BARC layer may be disposed directly on the silicon-containing layer or hardmask layer, and appropriately cured. Next, a photoresist, such as those used in 193 nm lithography, is disposed directly on the silicon-containing layer (in a trilayer process) or directly on the organic BARC layer (in a quadlayer process). The photoresist layer is then imaged (exposed) using patterned actinic radiation, and the exposed photoresist layer is then developed using the appropriate developer to provide a patterned photoresist layer.

The pattern is next transferred from the photoresist layer to the layer directly below it, by appropriate etching techniques known in the art, such as by plasma etching, resulting in a patterned silicon-containing layer in a trilayer process or a patterned organic BARC layer in a quadlayer process. If a quadlayer process is used, the pattern is next transferred from the organic BARC layer to the silicon-containing layer or hardmask layer using appropriate pattern transfer techniques, such as plasma etching.

In an embodiment, the antireflective layer, e.g., a silicon-based oxide film, and the photoresist underlayer film are sequentially subjected to dry etching using the resist pattern as a mask. The silicon-based oxide film and the resist underlayer film may be subjected to dry etching using a known dry etching system. A source gas used for dry etching may include an oxygen-containing gas (e.g., O₂, CO, or CO₂), an inert gas (e.g., He, N₂, or Ar), a chlorine-based gas (e.g., Cl₂ or BCl₄), a fluorine-based gas (e.g., CHF₃ or CF₄), H₂, NH₃, or the like may be used depending on the elemental composition of the etching target. Moreover, any two or more of these etch gases may be used in combination.

In another embodiment, the silicon-based oxide film can be subjected to wet etching, e.g., using a hydrogen fluoride aqueous solution, a hydrofluoric acid-based buffer solution, or the like. Examples of the hydrofluoric acid-based buffer solution include a mixed solution of a hydrogen fluoride aqueous solution and ammonium fluoride (weak alkali).

After the silicon-containing layer or hardmask layer is patterned, the cured photoresist underlayer is then patterned using appropriate etching techniques, such as O₂ or CF₄ plasma. Any remaining patterned photoresist and organic BARC layers are removed during etching of the cured underlayer.

In an embodiment, the patterned photoresist underlayer is then subjected to the metal precursor, either as a gas (metal precursor vapor) with or without a carrier gas, or as a solution including the metal precursor, as described herein. In this manner, the metal precursor infiltrates a free volume of the photoresist underlayer. The step of subjecting can also include a purge step in which metal precursor that is not in some manner affixed to the patterned photoresist underlayer can be removed from the photoresist underlayer. In the case of the described VPI process, a purge cycle may include subjecting the photoresist underlayer under a partial vacuum or with an inert gas flow, or both. In the case of the described LPI process, a purge cycle may include subjecting the photoresist underlayer under a partial vacuum with optional heating to remove most if not all of the solvent present in the metal solution impregnated photoresist underlayer. The step of subjecting the photoresist underlayer to the gas or liquid metal precursor followed by an optional purge step can be repeated one or more times.

Following the impregnation of the metal precursor into the patterned photoresist underlayer, the metal precursor-treated photoresist underlayer is exposed to an oxidizing agent as described to provide a patterned metallized photoresist underlayer. The step of exposing the photoresist underlayer to the oxidizing agent can be repeated one or more times.

It is to be understood that the step of subjecting the photoresist underlayer to the metal precursor as either a metal gas (vapor) or a metal solution followed by an optional purge, and then exposing the photoresist underlayer with the infiltrated metal precursor with the oxidizing agent followed by an optional purge can be repeated one or more times as a subjecting/exposing cycle to provide the metallized photoresist underlayer.

The pattern is then transferred to the substrate, such as by appropriate etching techniques, which also removes any remaining silicon-containing layer or hardmask layer, followed by removal of any remaining patterned cured underlayer to provide a patterned substrate.

Optionally, one or more barrier layers may be disposed on the photoresist layer. Suitable barrier layers include a topcoat layer, a top antireflectant coating layer (or TARC layer), and the like. Preferably, a topcoat layer is used when the photoresist is patterned using immersion lithography. Such topcoats are well-known in the art and are generally commercially available, such as OC™ 2000 available from DuPont Electronics & Imaging. It will be appreciated by those skilled in the art that a TARC layer is not needed when an organic antireflectant layer is used under the photoresist layer.

Photoresist underlayers formed from the SOC compositions show excellent planarization, good solvent resistance, and tunable etch selectivity. Preferred photoresist underlayer compositions of the invention may, as a result, be useful in a variety of semiconductor manufacturing processes.

The present inventive concept is further illustrated by the following examples. All compounds and reagents used herein are available commercially except where a procedure is provided below.

### EXAMPLES

Gel Permeation Chromotogtaphy (GPC). Number and weight-average molecular weights, Mₙ and M_{w}, and polydispersity (PDI) values (M_{w}/Mₙ) for the polymers are measured by GPC on an Agilent 1100 series LC system equipped with an Agilent 1100 series refractive index and MiniDAWN light scattering detector (Wyatt Technology Co.). Samples are dissolved in HPLC grade THF at a concentration of approximately 10 mg/mL and filtered through at 0.45 μm syringe filter, then injected through four Shodex columns (KF805, KF804, KF803 and KF802). A flow rate of 1 mL/min and temperature of 35° C. is maintained. The columns are calibrated with narrow molecular weight PS standards (EasiCal PS-2, Polymer Laboratories, Inc.).

Differential scanning calorimetry (DSC) is used to determine glass transition temperatures of the polymers. Polymer samples (1-3 mg) are heated to and maintained at 150° C. for 10 min to remove residual solvent on the first cycle, then cooled to 0° C. and ramped back up to 300° C. at a heating rate of 10° C./min. The second heating curve and reversible heating curves are used to identify glass transition temperatures.

### Example P1, Styrene/4-Acetoxystyrene/Hydroxyethyl Acrylate

To a round bottom flask is added 5.0 g styrene, 7.80 g 4-acetoxystyrene, 2.82 g hydroxyethyl acrylate, 1.41 g 2,2′-azobis(2-methylpropionate) (V-601) and 35.0 g propylene glycol monomethyl ether acetate (PGMEA). The reaction mixture is bubbled with N₂ with stirring for 15 minutes, and warmed to 90° C. and left to stir for 20 hrs. The reaction mixture is cooled to room temperature and poured into 800 mL of 4/1 methanol/water to give a solid polymer product. The product is filtered off and washed in excess 4/1 methanol/water, then air-dried for 4 hrs and vacuum-dried at 50° C. for an additional 20 hrs to provide polymer P1. (13.0 g yield, Mw=8540, PDI=2.0).

### Examples P2, P3, and P4

Polymers of Example P2, Example P3, and Example P4 are made with a similar procedure as for Example P1 with the exception that the corresponding respective monomer is used in the appropriate mole amounts to provide the desired polymers. In the polymer P3, q is about 10-15. The polymer of Example P2, Example P3, and Example P4 are listed and summarized in Table 1.

### Comparative Example CP1 and CP3

Comparative Example CP1 and CP3 are made with a similar procedure as for Example P1 with the exception that the corresponding respective monomer is used in the appropriate mole amounts to provide the desired polymer. The polymer of CP1 and CP3 are listed and summarized in Table 1.

### Comparative Example CP2, 9-Anthracenylmethyl Methacrylate/Hydroxy Adamantyl Methacrylate

To a round bottom flask is added 12.0 g 9-anthracenylmethyl methacrylate, 2.59 g hydroxy adamantyl methacrylate, 1.36 g 2,2′-azobis(2,4-dimethylvaleronitrile) (V-65), and 35.0 g tetrahydrofuran (THF). The reaction mixture is bubbled under N₂ with stirring for 15 minutes, and then warmed to 69° C. and left to stir for 20 hours. The reaction mixture is cooled to room temperature and poured into 800 mL methanol to provide a solid polymer product. The polymer is separated by filtration and washed in excess methanol, then air-dried for 4 hrs and vacuum-dried at 50° C. for an additional 20 hrs to give polymer CP2. (14.6 g yield, Mw=5790, PDI=2.2).

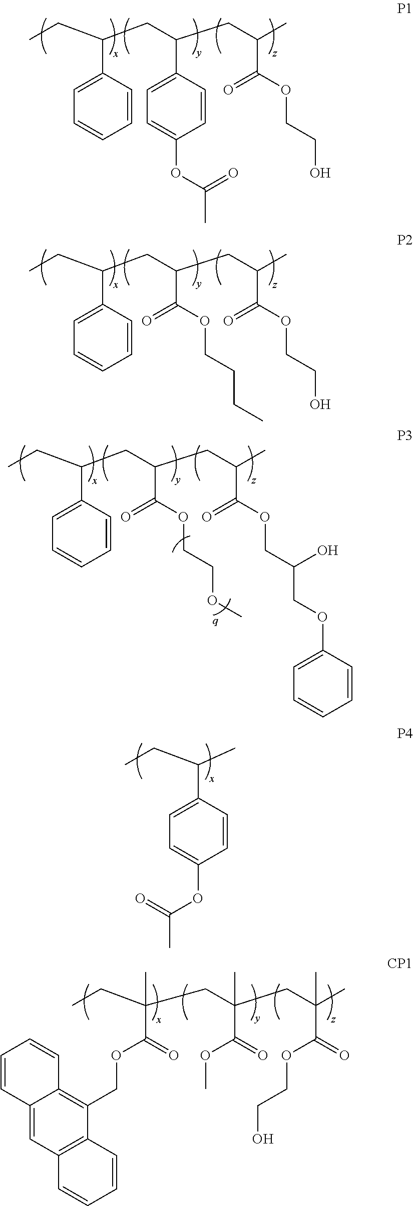

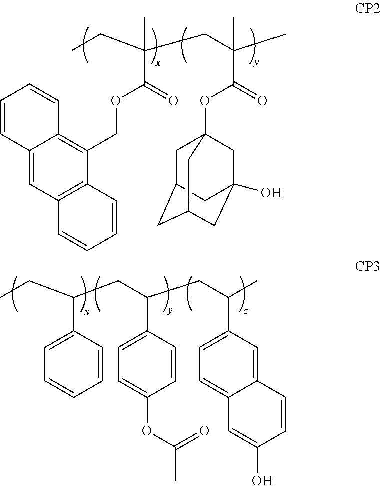

TABLE 1
Molecular weight and thermal characterization of polymers

| | Mon- | Mon- | Mon- | | | | |
|---|---|---|---|---|---|---|---|
| | omer | omer | omer | | | | |
| Polymer | 1 (x) | 2 (y) | 3 (z) | Mn | Mw | PDI | Tg |
| P1 | 40 | 40 | 20 | 4340 | 8540 | 2.0 | 68° C. |
| P2 | 60 | 20 | 20 | 3150 | 6040 | 1.9 | 20° C. |
| P3 | 70 | 10 | 20 | 4530 | 9610 | 2.1 | 6° C. |
| P4 | 100 | | | 4840 | 10360 | 2.1 | 97° C. |
| CP1 | 54 | 23 | 23 | 2840 | 6930 | 2.4 | 124° C. |
| CP2 | 80 | 20 | | 2600 | 5790 | 2.2 | 113° C. |
| CP3 | 60 | 20 | 20 | 4130 | 7880 | 1.9 | 112° C. |

### Example Formulations

Photoresist underlayer compositions are prepared by dissolving the polymers as listed in Table 1 having a weight percent of 17.6 wt % to 20 wt % in the presence of other additives set forth in Table 2 (components in wt %) and 80 wt % cyclohexanone to form SOC compositions. The SOC compositions are filtered through a 0.2 μm ultra-high molecular weight polyethylene (UPE) syringe filter prior to spin coating.

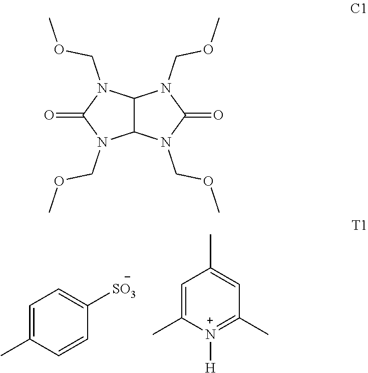

F1=PolyFox 656

TABLE 2
SOC Compositions

| | | Additive | Additive | Additive |
|---|---|---|---|---|
| Example | Polymer 1 | C1 | T1 | F1 |
| 1 | P1 (18.9) | (0.9) | (0.16) | (0.02) |
| 2 | P2 (18.5) | (1.3) | (0.16) | (0.02) |
| 3 | P3 (18.7) | (1.1) | (0.16) | (0.02) |
| 4 | P4 (20) | | | (0.02) |
| C1 | CP1 (17.6) | (2.2) | (0.16) | (0.02) |
| C2 | CP2 (18.5) | (1.3) | (0.16) | (0.02) |
| C3 | CP3 (18.7) | (1.1) | (0.16) | (0.02) |

As indicated in Table 1, polymers P1, P2, P3, and P4 each have a T_{g} of less than 110° C. and comparative example polymers CP1, CP2, and CP3 each have a T_{g} of greater than 110° C. Consideration as to how the Tg may be lowered in a series of structural like polymers one can make a comparison of polymers P1 with CP3. Both P1 and CP3 are prepared from the monomers, styrene and 4-acetoxystyrene, albeit in respective different amounts (P1 having a mole ratio of styrene: 4-acetoxystyrene of 1:1 and in CP3 the mole ratio is 3:1). Moreover, the third monomer in P1 is hydroxyethyl acrylate (0.2) and in CP3 the third monomer is 1-hydroxy-6-vinylnaphthalene (0.2). The difference in T_{g} between P1 and CP3 is 44° C. We suspect that the more structurally rigid hydroxynaphthyl vs. aliphatic hydroxyethyl chain may play a role in the lowering of the T_{g} in P1. In fact, this is supported by the observed difference in T_{g} between P1 and P2, the latter have a lower T_{g} of 20° C. The observed difference in P1 and P4 further supports the presence of side chains such as hydroxyethyl to lower T_{g}.

Formulations 1-4 and C1-C3 are coated unto a substrate and baked at 205° C./60 s. Film thicknesses before and after metallization (MTLZ), see below, are measured by ellipsometry and are summarized in Table 3.

### Process of Metal Precursor Infiltration

The photoresist underlayer films are each subjected to a metallization process whereby they are exposed to metal precursors and oxidants according to the following process. Wafers coated with cured photoresist underlayer are placed into a reactor chamber that is heated and maintained at 150° C. N₂ is flowed at 2 sccm until pressure stabilized at 60 mTorr, and then the chamber sealed and held for 0.5 s. Trimethylaluminum gas is pulsed into the chamber for 0.15 s followed by a wait period of 60 s. N₂ is then flowed into the chamber at 20 sccm for 90 s, and then reduced to 2 sccm until pressure is stabilized at 60 mTorr. Water is pulsed into the chamber for 0.15 s followed by a wait period of 60 s. N₂ is flowed into the chamber at 20 sccm for 90 s. The chamber is cooled to room temperature and the wafers removed.

### XSEM-EDX Analysis

Cross-sections of the metal infiltrated photoresist underlayers are visualized with KLA-Tencor Amray 4200 SEM with EDX. Samples are sputter coated with Iridium. EDX is taken using an accelerating voltage of 5.0 kV.

TABLE 3
Photoresist Underlayer thickness and metal detection following
metallization with trimethylaluminum and water

| | FT before | FT after | % | Al detection |
|---|---|---|---|---|
| Example | VPI (nm) | VPI (nm) | swelling | (XSEM-EDX) |
| 1 | 1078 | 1163 | 7.9% | Yes |
| 2 | 995 | 1110 | 11.6% | Yes |
| 3 | 913 | 939 | 2.9% | Yes |
| 4 | 1194 | 1204 | 0.8% | Yes |
| C1 | 788 | 822 | 4.3% | Not detected |
| C2 | 1193 | 1209 | 1.3% | Not detected |
| C3 | 1060 | 1058 | −0.2% | Not detected |

As seen in Table 3, the inventive photoresist underlayer films have detectable metal content whereas metal sites are not detected in the comparative photoresist underlayer films (C1, C2, and C3) prepared with SOC compositions with polymers having a Tg of greater than 110° C. Accordingly, we demonstrate that the lowering of Tg of the polymer present in the SOC composition is an important requirement for achieving organic-inorganic (metallized) hybrid photoresist underlayers. Moreover, we demonstrate that the lowering of Tg of the polymer present in the SOC composition provides a more uniformly metallized content with respect to film depth of the photoresist underlayer, and therefore, provides relatively uniform etch resistance for the photoresist underlayer.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A method of forming a pattern on a substrate, the method comprising:
forming a photoresist underlayer over a surface of the substrate, wherein the photoresist underlayer is formed from a composition comprising a polymer having a glass transition temperature of less than 110° C. and a solvent;
subjecting the photoresist underlayer to a metal precursor, wherein the metal precursor infiltrates a free volume of the photoresist underlayer; and
exposing the metal precursor-treated photoresist underlayer to an oxidizing agent to provide a metallized photoresist underlayer.

2. The method of claim 1, wherein prior to the subjecting of the photoresist underlayer to the metal precursor, the method further comprises:
forming an antireflective coating layer over the photoresist underlayer and a photoresist layer over the antireflective coating layer;
exposing the photoresist layer to activating radiation and developing the exposed photoresist layer to form a photoresist pattern; and
transferring the photoresist pattern by etching to the antireflective coating layer and the photoresist underlayer.

3. The method of claim 1, wherein the metal precursor comprises a metal chosen from aluminum, tin, tungsten, titanium, molybdenum, hafnium, or a combination thereof.

4. The method of claim 1, wherein the polymer has a glass transition temperature of greater than 0° C. and less than 100° C.

5. The method of claim 1, wherein the polymer comprises a functional group selected from a keto-carbonyl, an ester, a hydroxy, acetal, ketal, carboxylic acid, amide, carbamate, urea, carbonate, aldehyde, imide, sulfonic acid, sulfonate ester, or a combination thereof.

6. The method of claim 1, wherein the polymer comprises polymerized units of monomer units chosen from acrylates, methacrylates, acrylamides, methacrylamides, vinyl ethers, vinyl aromatics, or a combination thereof.

7. The method of claim 1, wherein the polymer comprises a monomer unit of Formula (1) 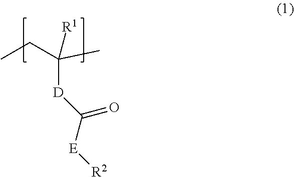
wherein in Formula (1),
D is absent, —O—, —(CHR^{a})ₙ—, —(CHR^{a}CHR^{b}O)ₘ—, optionally substituted C₆₋₁₄ arylene, optionally substituted C₃₋₁₈ heteroarylene, optionally substituted C₅₋₁₂ cycloalkylene, or a combination thereof, wherein each R^{a} and each R^{b} is independently hydrogen, or substituted or unsubstituted C₁₋₆ alkyl, and n is an integer of 1 to 12, and m is an integer of 1 to 8;
E is absent, —O—, —NR^{N}—, or E can join with D to from a ring;
R¹ and R^{N} are independently hydrogen, or substituted or unsubstituted C₁₋₆ alkyl; and
R² is hydrogen, substituted or unsubstituted C₁₋₁₆ alkyl, substituted or unsubstituted C₁₋₁₆ heteroalkyl, substituted or unsubstituted C₅₋₂₀ cycloalkyl, substituted or unsubstituted C₃₋₂₀ heterocycloalkyl, substituted or unsubstituted C₂₋₁₆ alkenyl, substituted or unsubstituted C₂₋₁₆ alkynyl, substituted or unsubstituted C₆₋₁₈ aryl, substituted or unsubstituted C₇₋₃₀ arylalkyl, substituted or unsubstituted C₇₋₃₀ alkylaryl, substituted or unsubstituted C₃₋₁₈ heteroaryl, substituted or unsubstituted C₄₋₃₀ heteroarylalkyl, or R² can join with D to form a ring.

8. The method of claim 7, wherein D is absent, —O—, —(CHR^{a})ₙ—, optionally substituted C₆₋₁₄ arylene, or a combination thereof; E is absent or —O—; and R² is hydrogen, substituted or unsubstituted C₁₋₁₀ alkyl, substituted or unsubstituted C₁₋₁₀ heteroalkyl with a total of one to four ether, ester, amide, or —C(O)— groups, unsubstituted C₆₋₁₄ aryl, C₆₋₁₄ aryl substituted with —OR³, —C(O)OR³, —C(O)N(R^{N})R³, or —C(O)R³, unsubstituted C₃₋₁₂ heteroaryl, or C₃₋₁₂ heteroaryl substituted with —OR³, —C(O)OR³, —C(O)N(R^{N})R³, or —C(O)R³, wherein R³ is H, or substituted or unsubstituted C₁₋₆ alkyl.

9. The method of claim 1, wherein the polymer comprises a monomer unit of Formula (2) 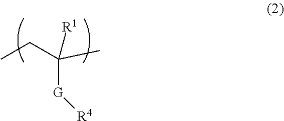
wherein in Formula (2),
G is absent, —(CHR^{a})ₙ—, —(CHR^{a}CHR^{b}O)ₘ—, —O—, —C(O)O—, —C(O)OR⁵—, —C(O)—, —C(O)N(R^{N})—, optionally substituted C₆₋₁₄ arylene, optionally substituted C₃₋₁₃ heteroarylene, or optionally substituted C₅-C₁₂ cycloalkylene, wherein R¹, R^{N}, each R^{a} and each R^{b}, is independently hydrogen, optionally substituted C₁₋₆ alkyl, an optionally substituted C₆₋₁₄ aryl, or an optionally substituted C₃₋₁₃ heteroaryl; and n is an integer of 1 to 12, and m is an integer of 1 to 8;
R⁴ is hydrogen, optionally substituted C₁₋₁₀ alkyl, optionally substituted C₁₋₁₀ heteroalkyl with a total of one to four ether, ester, amide, or —C(O)— groups, optionally substituted C₂₋₁₀ alkenyl, optionally substituted C₂₋₁₀ alkynyl, optionally substituted C₆₋₁₄ aryl, or optionally substituted C₃₋₁₂ heteroaryl, and
R⁵ is an optionally substituted C₁₋₄ alkylene or C₂₋₄ alkenylene.

10. The method of claim 1, further comprising curing the photoresist underlayer to crosslink the polymer prior to the subjecting of the photoresist underlayer to the metal precursor.
